(19) United States
(12) Patent Application Publication
(10) Pub. No.: US 2025/0300481 A1
(43) Pub. Date: Sep. 25, 2025

(54) CHARGING OR DISCHARGING CONTROL CIRCUIT AND BATTERY DEVICE

(71) Applicant: ABLIC Inc., Nagano (JP)

(72) Inventor: Shinya FUKUCHI, Nagano (JP)

(73) Assignee: ABLIC Inc., Nagano (JP)

(21) Appl. No.: 19/021,195

(22) Filed: Jan. 15, 2025

(30) Foreign Application Priority Data
Mar. 19, 2024 (JP) 2024-043135

(51) Int. Cl. H02J 7/00; H01M 10/46; H01M 10/48; H01M 50/51

(52) U.S. Cl. CPC H02J 7/007182; H01M 10/46; H01M 10/482; H01M 50/51; H02J 7/0013; H02J 7/0047

(57) ABSTRACT

A charging or discharging control circuit includes a constant current source that flows a detection current, multiple voltage detection circuits connected in parallel to each of multiple secondary batteries, and a control circuit that receives outputs of the voltage detection circuits. The voltage detection circuit includes a voltage dividing circuit that outputs a divided voltage based on an input voltage between a positive input port and a negative input port, a reference voltage source that outputs a reference voltage, a first comparator circuit that receives and compares the divided voltage and the reference voltage, a second comparator circuit that receives and compares potentials of the positive input port and the negative input port, and switches that block an input voltage to the first comparator circuit. The control circuit, in response to the intermediate terminal being detached, blocks the input voltage to the first comparator circuit.

### CROSS-REFERENCE TO RELATED APPLICATION

This application claims the priority benefits of Japanese application no. 2024-043135, filed on Mar. 19, 2024. The entirety of the above-mentioned patent application is hereby incorporated by reference herein and made a part of this specification.

### BACKGROUND

### Technical Field

The present invention relates to a charging or discharging control circuit and a battery device.

### Description of Related Art

In a battery device including a plurality of secondary batteries connected in series, if a disconnection occurs at the connection part between the secondary battery and the charging or discharging control circuit (hereinafter referred to as an intermediate terminal detachment), the charging or discharging control of the secondary battery becomes impossible. That is, even if the secondary battery is overcharged or over-discharged, it becomes impossible to detect and control this condition, thereby causing stress to the secondary battery.

As an example of a technology for detecting such an intermediate terminal detachment, a technology has been proposed to detect the intermediate terminal detachment by using a comparator circuit to detect the voltage change between two points that changes before and after the intermediate terminal detachment (for example, refer to Patent Document 1, Japanese Patent Application Laid-Open (JP-A) No. 2015-1446).

The present invention is described using an example of a battery device including a plurality of secondary batteries connected in series. In the battery device illustrated in FIG. 3, in the case where the connection between the intermediate terminal VC3 and the secondary battery is detached, that is, in the case where an intermediate terminal detachment occurs, the intermediate terminal VC3 is pulled up and exceeds the voltage of the intermediate terminal VC2, meaning the inter-terminal voltage between the intermediate terminal VC2 and the intermediate terminal VC3 changes. By detecting this change in the inter-terminal voltage using the comparator circuit C22, it is possible to detect the state where the intermediate terminal is detached.

However, in the state where the intermediate terminal VC3 is detached, there is room for improvement from the perspective that the voltage of the intermediate terminal VC3 rises (apparently) to an overcharge voltage, and a voltage exceeding the voltage of the reference voltage source VR3 continues to be received by the comparator circuit C13 for a long period, causing deterioration of the characteristic of the transistors constituting the comparator circuit C13, deterioration of the offset characteristic of the comparator circuit C13, and deterioration of the characteristic of the detection voltage.

The present invention is made in consideration of the above-mentioned circumstances, and provides a charging or discharging control circuit and a battery device that prevent the characteristic deterioration of the detection voltage due to intermediate terminal detachment.

### SUMMARY

The charging or discharging control circuit of the present invention includes:
a positive power source connection terminal, an intermediate terminal, and a negative power source connection terminal, which are respectively connected to a positive terminal, a battery interconnecting terminal, and a negative terminal of a plurality of secondary batteries connected in series;
a constant current source, flowing a detection current between the positive power source connection terminal and the intermediate terminal, between adjacent intermediate terminals, and between the intermediate terminal and the negative power source connection terminal;
a plurality of voltage detection circuits, connected in parallel to each of the plurality of secondary batteries; and
a control circuit, receiving outputs of the plurality of voltage detection circuits.
   The voltage detection circuit includes:
a voltage dividing circuit, outputting a divided voltage based on an input voltage between a positive input port and a negative input port;
a reference voltage source, outputting a reference voltage;
a first comparator circuit, receiving and comparing the divided voltage and the reference voltage;
a second comparator circuit, receiving and comparing potentials of the positive input port and the negative input port; and
a switch, blocking an input voltage to the first comparator circuit.
   The control circuit, in response to the intermediate terminal being detached,
based on a detection signal output by the second comparator circuit,
blocks the input voltage to the first comparator circuit.

### BRIEF DESCRIPTION OF THE DRAWINGS

FIG. 1 is a circuit diagram of the charging or discharging control circuit and the battery device according to the embodiment.

FIG. 2 is a circuit diagram of the charging or discharging control circuit and the battery device according to the embodiment.

FIG. 3 is a circuit diagram of the conventional charging or discharging control circuit and the battery device.

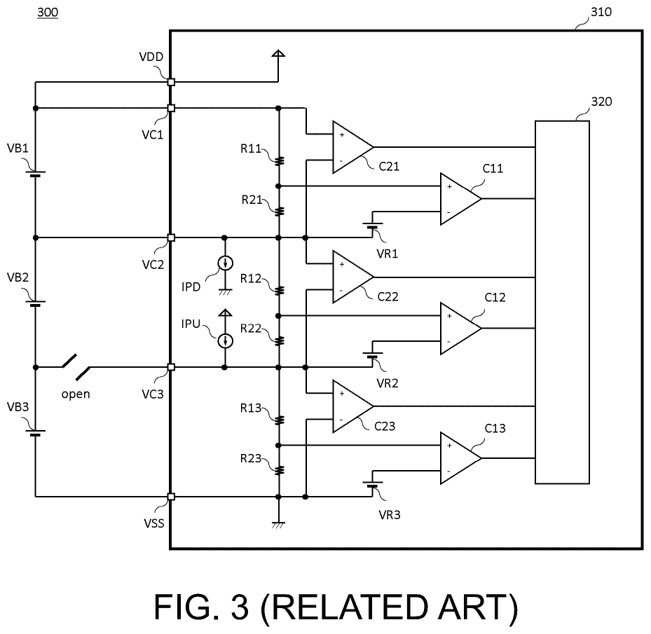

### DESCRIPTION OF THE EMBODIMENTS

According to the present invention, it is possible to prevent characteristic deterioration of the detection voltage due to intermediate terminal detachment.

The embodiments of the present invention are described in detail below based on the drawings. It is noted that in all figures for describing the embodiments, the same parts are basically given the same reference numerals, and repetitive descriptions thereof are basically omitted. Further, in the specification, components whose reference numerals end with “n” are expressed as “n=1 to 3” to replace the description three times.

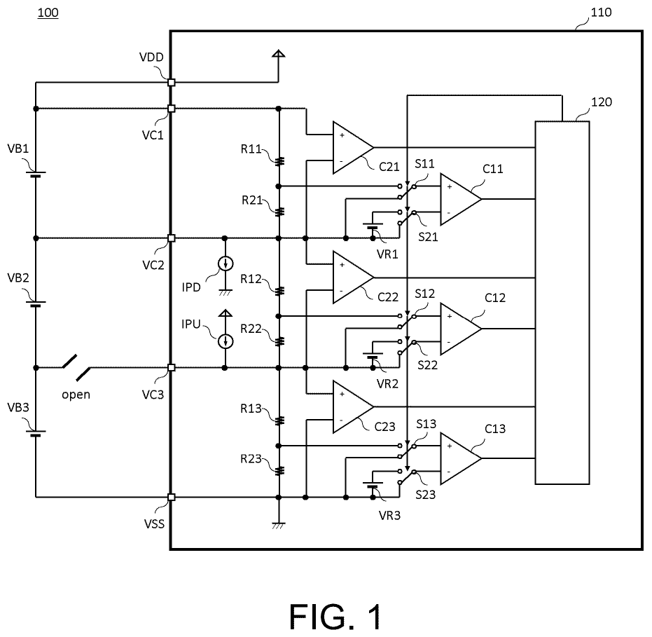

FIG. 1 is a circuit diagram of the battery device including the charging or discharging control circuit according to the embodiment. The battery device 100 includes secondary batteries VB1, VB2, and VB3, and a charging or discharging control circuit 110. The charging or discharging control circuit 110 includes power source terminals VDD and VSS, input ports VC1, VC2, and VC3, constant current sources IPD and IPU, a control circuit 120, and three voltage detection circuits. Each voltage detection circuit includes a voltage dividing circuit, a reference voltage source VRn, comparator circuits C1n and C2n, and switches S1n and S2n, and the voltage dividing circuit includes resistors R1n and R2n (n=1 to 3).

The secondary battery VB1 has its positive terminal connected to the input port VC1 and the power source terminal VDD, and its negative terminal connected to the input port VC2. The secondary battery VB2 has its positive terminal connected to the input port VC2, and its negative terminal connected to the input port VC3. The secondary battery VB3 has its positive terminal connected to the input port VC3, and its negative terminal connected to the power source terminal VSS. The input ports VC2 and VC3 may be considered as intermediate terminals as they are not connected to the power source terminals VDD and VSS. The constant current source IPD is connected between the input port VC2 and the power source terminal VSS. The constant current source IPU is connected between the power source terminal VDD and the input port VC3.

The resistor R11 and the resistor R21 are connected in series between the input port VC1 and the input port VC2. The connection point of the resistor R11 and the resistor R21 is connected to the non-inverting input port of the comparator circuit C11 through the switch S11. The reference voltage source VR1 has its negative terminal connected to the input port VC2, and its positive terminal connected to the inverting input port of the comparator circuit C11 through the switch S21. The output port of the comparator circuit C11 is connected to the control circuit 120. The comparator circuit C21 has its non-inverting input port connected to the input port VC1, its inverting input port connected to the input port VC2, and its output port connected to the control circuit 120.

The resistor R12 and the resistor R22 are connected in series between the input port VC2 and the input port VC3. The connection point of the resistor R12 and the resistor R22 is connected to the non-inverting input port of the comparator circuit C12 through the switch S12. The reference voltage source VR2 has its negative terminal connected to the input port VC3, and its positive terminal connected to the inverting input port of the comparator circuit C12 through the switch S22. The output port of the comparator circuit C12 is connected to the control circuit 120. The comparator circuit C22 has its non-inverting input port connected to the input port VC2, its inverting input port connected to the input port VC3, and its output port connected to the control circuit 120.

The resistor R13 and the resistor R23 are connected in series between the input port VC3 and the power source terminal VSS. The connection point of resistor R13 and resistor R23 is connected to the non-inverting input port of the comparator circuit C13 through the switch S13. The reference voltage source VR3 has its negative terminal connected to the power source terminal VSS, and its positive terminal connected to the inverting input port of the comparator circuit C13 through the switch S23. The output port of the comparator circuit C13 is connected to the control circuit 120. The comparator circuit C23 has its non-inverting input port connected to the input port VC3, its inverting input port connected to the power source terminal VSS, and its output port connected to the control circuit 120.

In FIG. 1, in response to the input port VC3, which is the intermediate terminal, being detached, the switches S1n and S2n of the comparator circuit C1n are controlled such that both input ports are connected to the negative terminal of the reference voltage source VRn (where n=1 to 3).

The constant current sources IPD and IPU flow a detection current to detect the intermediate terminal detachment. The constant current source IPD pulls down the input port VC2 in response to the connection between the input port VC2 and the secondary battery being detached. The constant current source IPU pulls up the input port VC3 in response to the connection between the input port VC3 and the secondary battery being detached.

The comparator circuits C1n detect the battery voltage, and the comparator circuits C2n detect the intermediate terminal detachment. The comparator circuits C11 and C21 monitor the voltage between the input port VC1 and the input port VC2. The comparator circuits C12 and C22 monitor the voltage between the input port VC2 and the input port VC3. The comparator circuits C13 and C23 monitor the voltage between the input port VC3 and the power source terminal VSS. The control circuit 120 receives the outputs from the comparator circuits Cn and C2n, and outputs signals to control the switches S1n and S2n (where n=1 to 3).

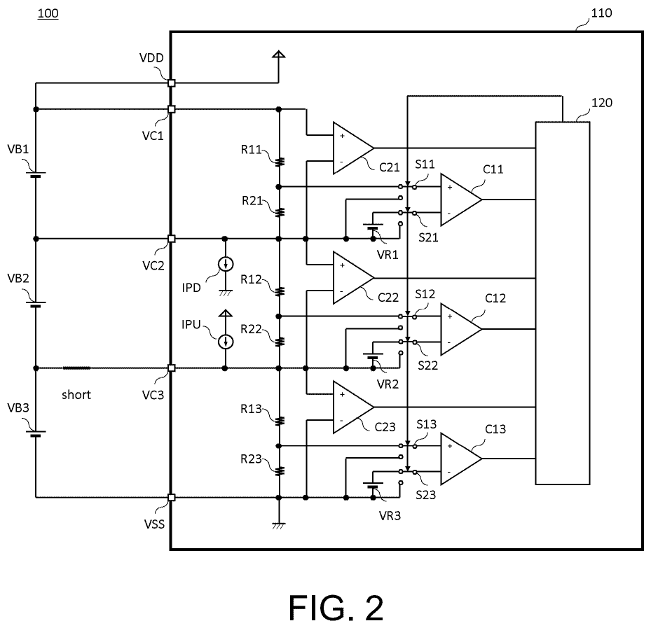

FIG. 2 is also a circuit diagram of the battery device including the charging or discharging control circuit according to the embodiment. The differences from FIG. 1 are that the input port VC3, which is the intermediate terminal, is not detached, and that the switches S1n and S2n are controlled such that the non-inverting input port of the comparator circuit C1n is connected to the connection point of the resistor R1n and the resistor R2n, and the inverting input port is connected to the positive electrode of the reference voltage source VRn (where n=1 to 3). Other aspects do not substantially differ from FIG. 1.

Next, the operation of the battery device including the charging or discharging control circuit of the embodiment is described. As illustrated in FIG. 2, when the charging or discharging control circuit 110 is monitoring the voltages of the secondary batteries VB1, VB2, and VB3, the connection between the input port VC3 and the secondary battery is not detached, that is, no intermediate terminal detachment has occurred. In this case, the voltage of the input port VC1>the voltage of the input port VC2, the voltage of the input port VC2>the voltage of the input port VC3, and the voltage of the input port VC3>the voltage of the power source terminal VSS. As a result, for the comparator circuits C2n, the voltage of the non-inverting input port>the voltage of the inverting input port, and the comparator circuits C2n output H level (where n=1 to 3).

The control circuit 120 outputs signals to control the switches S1n and S2n based on the output level of the comparator circuits C2n. In response to the comparator circuits C2n outputting H level, the control circuit 120 detects that no intermediate terminal detachment has occurred, and controls the switches S1n and S2n such that the non-inverting input port of the comparator circuit C1n is connected to the connection point of the resistor R1n and the resistor R2n, and the inverting input port of the comparator circuit C1n is connected to the positive terminal of the reference voltage source VRn (where n=1 to 3).

As illustrated in FIG. 1, when the charging or discharging control circuit 110 is monitoring the voltages of the secondary batteries VB1, VB2, and VB3, in the case where the connection between the input port VC3 and the secondary battery is detached, that is, when an intermediate terminal detachment occurs, the input port VC3 is pulled up by the constant current source IPU, and the voltage of the input port VC2<the voltage of the input port VC3. As a result, for the comparator circuit C22, the voltage of the non-inverting input port<the voltage of the inverting input port, and the comparator circuit C22 outputs L level.

Although not illustrated in the figure, in the case where the connection between the input port VC2 and the secondary battery is detached, the input port VC2 is pulled down by the constant current source IPD, and the voltage of the input port VC2<the voltage of the input port VC3. In this case as well, for the comparator circuit C22, the voltage of the non-inverting input port<the voltage at the inverting input port, and the comparator circuit C22 outputs L level.

In response to any of the comparator circuits C2n outputting L level, the control circuit 120 detects that an intermediate terminal detachment has occurred, and controls the switches S1n and S2n such that the input voltage of the comparator circuits C1n is reduced or cut off to the voltage level of the negative terminal of the reference voltage source VRn (where n=1 to 3).

Even if the intermediate terminal VC3 is detached and the voltage of the intermediate terminal VC3 rises (apparently) to the overcharge voltage, the input voltage at the input port of the comparator circuit C13 is reduced or cut off to the voltage level of the negative terminal of the reference voltage source VR3. As a result, the deterioration of the characteristic of the transistors constituting the comparator circuit C13 becomes less likely to occur, the deterioration of the offset characteristic of the comparator circuit C13 becomes less likely to occur, and the deterioration of the characteristic of the overcharge detection voltage may be prevented.

As described above, even if an intermediate terminal detachment occurs, the input port of the comparator circuit for detecting the battery voltage may be cut off, and because a voltage exceeding the reference voltage is not received by the comparator circuit for a long period, the deterioration of the characteristic of the detection voltage may be prevented.

It is noted that while a case of connecting three secondary batteries has been described, the number of secondary batteries is not limited thereto. Further, the detection voltage capable of preventing the characteristic deterioration, which is an effect of the present invention, is not limited to the overcharge detection voltage. Further, although constant current sources are used as means for pulling up or pulling down the intermediate terminals, this is not limited thereto. Furthermore, it is not limited to whether the constant current source has or does not have periods during which it flows or does not flow the detection current.

These embodiments and the modifications thereof are included within the scope and gist of the invention, as well as within the scope of the invention described in the claims and its equivalents.

What is claimed is:

1. A charging or discharging control circuit, comprising:
a positive power source connection terminal, an intermediate terminal, and a negative power source connection terminal, which are respectively connected to a positive terminal, a battery interconnecting terminal, and a negative terminal of a plurality of secondary batteries connected in series;
a constant current source, flowing a detection current between the positive power source connection terminal and the intermediate terminal, between adjacent intermediate terminals, and between the intermediate terminal and the negative power source connection terminal;
a plurality of voltage detection circuits, connected in parallel to each of the plurality of secondary batteries; and
a control circuit, receiving outputs of the plurality of voltage detection circuits,
the voltage detection circuit comprising:
a voltage dividing circuit, outputting a divided voltage based on an input voltage between a positive input port and a negative input port;
a reference voltage source, outputting a reference voltage;
a first comparator circuit, receiving and comparing the divided voltage and the reference voltage;
a second comparator circuit, receiving and comparing potentials of the positive input port and the negative input port; and
a switch, blocking an input voltage to the first comparator circuit, and
wherein the control circuit, in response to the intermediate terminal being detached,
based on a detection signal output by the second comparator circuit,
blocks the input voltage to the first comparator circuit.

2. The charging or discharging control circuit according to claim 1, wherein the constant current source has a period during which the detection current does not flow.

3. A battery device, comprising:
a plurality of secondary batteries connected in series; and
a charging or discharging control circuit according to claim 1 that controls charging or discharging of the plurality of secondary batteries.

4. A battery device, comprising:
a plurality of secondary batteries connected in series; and
a charging or discharging control circuit according to claim 2 that controls charging or discharging of the plurality of secondary batteries.
